(19) United States
(12) Patent Application Publication
(10) Pub. No.: US 2026/0107832 A1
(43) Pub. Date: Apr. 16, 2026

(54) BACKSIDE DEEP TRENCH CAPACITOR

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Jingyun Zhang, Albany, NY (US); Oleg Gluschenkov, Tannersville, NY (US)

(21) Appl. No.: 18/911,992

(22) Filed: Oct. 10, 2024

(51) Int. Cl. H01L 25/16; H01L 23/00; H01L 23/48

(52) U.S. Cl. CPC H10W 90/00; H10D 1/042; H10D 1/716; H10W 20/20; H10W 80/312; H10W 80/327; H10W 90/792

(57) ABSTRACT

A semiconductor device is provided in which a backside deep trench capacitor is prebuilt and then integrated on a backside of the semiconductor device utilizing a hybrid bonding process. The hybrid bonding process forms a hybrid bonding interface on the backside of the semiconductor device which contains dielectric-to-dielectric bonds and metal-to-metal bonds.

### BACKGROUND

The present application relates to semiconductor technology, and more particularly to a semiconductor device including a backside deep trench capacitor that is prebuilt and then integrated on a backside of the semiconductor device utilizing a hybrid bonding process.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance).

### SUMMARY

A semiconductor device is provided in which a backside deep trench capacitor is prebuilt and then integrated on a backside of the semiconductor device utilizing a hybrid bonding process. The hybrid bonding process forms a hybrid bonding interface on the backside of the semiconductor device which contains dielectric-to-dielectric bonds and metal-to-metal bonds. The prebuilt and then hybrid bonded backside deep trench capacitor extends the feasibility of backside contacting.

In one aspect of the present application, a semiconductor device is provided. In one embodiment of the present application, the semiconductor device includes a first transistor located in a capacitor region, a backside deep trench capacitor located beneath the first transistor, and a backside back-end-of-the-line (BEOL) structure located beneath the backside deep trench capacitor. In this embodiment, the backside deep trench capacitor is electrically connected to a source/drain region of the first transistor by a combination of a second plate electrode interconnect structure, a first level metal structure and a backside source/drain contact structure and a hybrid bonding interface is present between the second plate electrode interconnect structure and the first level metal structure.

In another aspect of the present application, the semiconductor device includes a first transistor and a backside deep trench capacitor located in a capacitor region, a second transistor located in a logic device region that is located adjacent to the capacitor region, and a backside BEOL structure located beneath the backside deep trench capacitor and beneath the second transistor. In this embodiment, the backside deep trench capacitor is electrically connected to a source/drain region of the first transistor by a combination of a second plate electrode interconnect structure, a first level metal structure and a backside source/drain contact structure, and the backside BEOL structure is electrically connected to a source/drain region of the second transistor by a combination of a through via structure, a through-via interconnect structure, a logic device first level metal structure and a logic device backside source/drain contact structure, and a hybrid bonding interface is present between the second plate electrode interconnect structure and the first level metal structure and between the through-via interconnect structure and the logic device first level metal structure.

### BRIEF DESCRIPTION OF THE DRAWINGS

FIG. 1 is a top down view of a device layout that can be employed in the present application, the device layout including a logic device region and a capacitor region.

FIG. 2 is a cross sectional view of a first exemplary structure in the logic device region and a second exemplary structure in the capacitor region and through cut Y-Y that can be employed in accordance with an embodiment of the present application.

FIG. 3 is a cross sectional view of the first exemplary structure and the second exemplary structure shown in FIG. 2 after wafer flipping, and removal of a semiconductor base layer.

FIG. 4 is a cross sectional view of the first exemplary structure and the second exemplary structure shown in FIG. 3 after removing an etch stop layer and a semiconductor device layer, and forming a backside interlayer dielectric (ILD) layer.

FIG. 5 is a cross sectional view of the first exemplary structure and the second exemplary structure shown in FIG. 4 after forming backside source/drain contact structures.

FIG. 6 is a cross sectional view of the first exemplary structure and the second exemplary structure shown in FIG. 5 after forming backside first level metal structures.

FIG. 7A is a cross sectional view of a third exemplary structure including a semiconductor substrate, a deep trench capacitor partially formed in a deep trench opening that is located in the semiconductor substrate, and a dielectric layer.

FIG. 7B is a cross sectional view of the third exemplary structure shown in FIG. 7A after forming through via trenches into the dielectric layer and the semiconductor substrate.

FIG. 7C is a cross sectional view of the third exemplary structure shown in FIG. 7B after forming a through via liner and a through via metal structure in each of the through via trenches.

FIG. 7D is a cross sectional view of the third exemplary structure shown in FIG. 7C after forming an additional dielectric layer, and forming interconnect structures in the additional dielectric layer.

FIG. 8 is a cross sectional view of the first exemplary structure and the second exemplary structure shown in FIG. 6 after bonding the third exemplary structure illustrated in FIG. 7D on a backside of both the first and second exemplary structures.

FIG. 9 is a cross sectional view of the bonded structure shown in FIG. 8 after thinning the semiconductor substrate to reveal a bottommost surface of the through via metal structure.

FIG. 10 is a cross sectional view of the exemplary structure shown in FIG. 9 after forming a backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Deep trench capacitors were traditionally formed on the frontside of a semiconductor device and connected to a source/drain region of a transistor. With the advent of backside power delivery and space saving, there is an ongoing trend to form deep trench capacitors on the backside of the semiconductor device. With traditional backside processing, it is difficult to integrate (i.e., connect) a deep trench capacitor that is formed on the backside of a wafer with a transistor that is formed on the frontside of the wafer. One reason for this is that it is difficult to pattern a deep trench with backside metal lines.

A semiconductor device is provided in which a backside deep trench capacitor is prebuilt and then integrated on a backside of the semiconductor device utilizing a hybrid bonding process. The prebuilt and then hybrid bonded backside deep trench capacitor extends the feasibility of backside contacting.

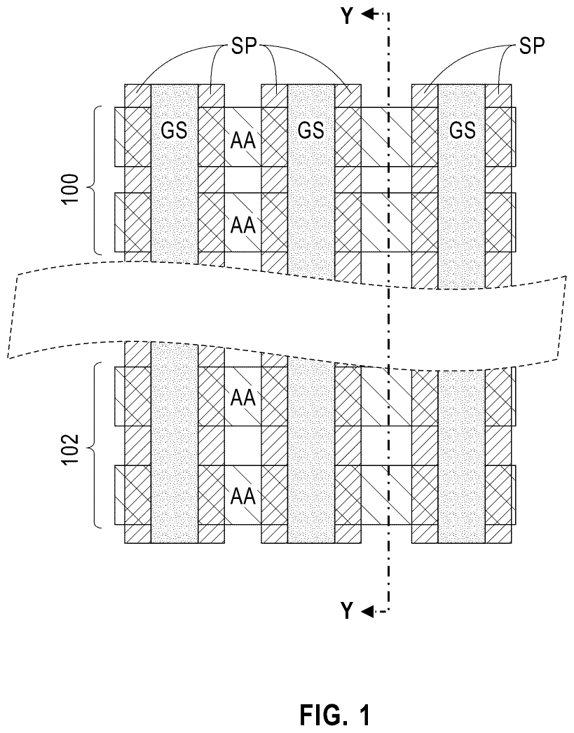

Referring first to FIG. 1, there is illustrated a device layout that can be employed in the present application. The device layout illustrated in FIG. 1 includes a logic device region 100 and a capacitor region 102. The capacitor region 102 is spaced apart from the logic device region 100 as shown by the doted region illustrated in FIG. 1. The dotted region is a region in which each gate structure, GS, is cut by a gate cut structure, not shown. Although the illustrated device layout includes logic device region 100, the present application works in embodiments in which the logic device region 100 is omitted or replaced with another type of device region. When present, the logic device region 100 is a region in which logic devices will be formed. The capacitor region 102 is a region in which a backside deep trench capacitor will be formed. The backside deep capacitor will be electrically connected to a source/drain region of a transistor present in the capacitor region 102. In FIG. 1, the logic device region 100 and the capacitor region 102 each include two active device areas. The two active device areas that are present in the logic device region 100 and the capacitor region 102 are separated by a non-active device area. A non-active device area is an area in which active semiconductor devices are not formed. The logic device region 100 and the capacitor region 102 also include at least one gate structure GS, three of which are shown by way of one example in FIG. 1. The gate structures, GS, run parallel to each other and perpendicular to the active device areas. Each gate structure, GS, present in the logic device region 100 passes through an active device area that is present in the logic device region 100, and each gate structure, GS, present in the capacitor region 102 passes through an active device area that is present in the capacitor region 102. Also, each gate structure includes a gate dielectric and a gate electrode. A gate spacer, SP, is located along a sidewall of each gate structure.

FIG. 1 further includes cut Y-Y that runs parallel to each gate structure. The cut Y-Y is located between the middle gate structure and the gate structure located on the right hand side of FIG. 1. The Y-Y cut is present in both the logic device region 100 and the capacitor region 102, and the Y-Y passes through areas in which a source/drain region of a transistor will be formed.

As used throughout the present application, a transistor (or field effect transistor (FET)) includes a source region, a drain region, a semiconductor channel region located between the source region and the drain region, and a gate structure contacting a portion of the semiconductor channel region. Collectively, the source region and the drain region can be referred to as a source/drain region. As used herein, a “source/drain” region can be a source region or a drain region depending on subsequent wiring and application of voltages during operation of the transistor. In some embodiments, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. In a nanosheet transistor, the gate structure wraps around each of the spaced apart semiconductor channel material nanosheets. Nanosheet transistors provide considerable scaling with high drive current capability. Nanosheet transistors provide a larger drive current for a given footprint compared to finFET technology. The present application is not limited to nanosheet transistors. Instead, the present application can be used for finFETs, nanowire FETs, planar FETs, fork sheet transistors, stacked FETs or any combination of such FETs including nanosheet transistors.

In a transistor and as is known to those skilled in the art, a gate dielectric material of the gate structure directly contacts a physically exposed surface(s) of the semiconductor channel region, and a gate electrode of the gate structure is formed on the gate dielectric material. The gate dielectric material has a dielectric constant of 4.0 or greater. All dielectric constants mentioned in the present application are measured in a vacuum unless otherwise noted. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to, aluminum (Al), tungsten (W), or cobalt (Co).

In the present application, a semiconductor device is provided that includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside BEOL structure. The backside BEOL structure can be a backside power distribution network that is capable of delivering power to the transistor through the backside of the semiconductor device.

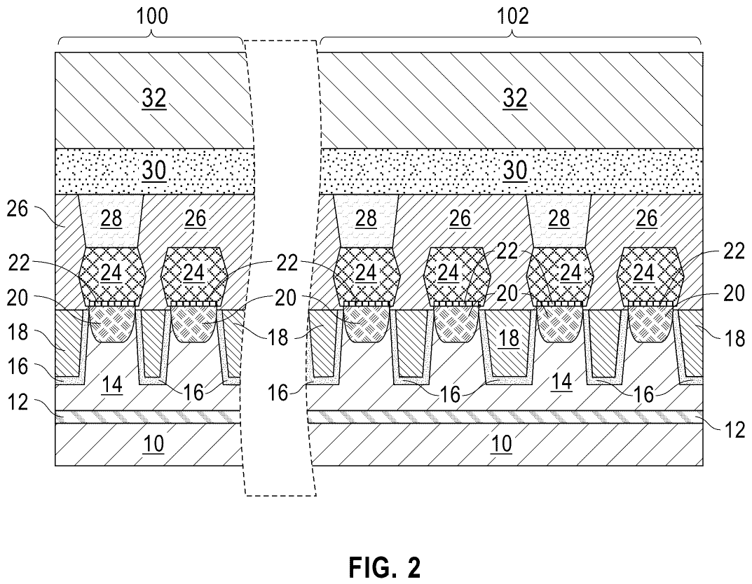

Referring now to FIG. 2, there is illustrated a first exemplary structure in the logic device region 100 and a second exemplary structure in the capacitor region 102 and through cut Y-Y that can be employed in accordance with an embodiment of the present application. At this point of the present application, the exemplary first structure in the logic device region 100 and the exemplary second structure in the capacitor region 102 are structurally identical. Notably, each exemplary structure, i.e., the exemplary first structure in the logic device region 100 and the exemplary second structure in the capacitor region 102, includes a substrate (including at least a semiconductor device layer 14), a shallow trench isolation structure including at least a trench dielectric material 18 present in an upper portion of the substrate (i.e., in an upper portion of the semiconductor device layer 14), and a transistor including a gate structure (not shown in the Y-Y cut), a semiconductor channel region (not shown in the Y-Y cut), and source/drain regions 24. The shallow trench isolation structure can also include a trench dielectric liner 16 located along a sidewall and a bottom surface of the trench dielectric material 18. The source/drain regions 24 are positioned above a backside source/drain contact placeholder structure 20 that is located in the semiconductor device layer 14 of the substrate. In some embodiments, a semiconductor buffer layer 22 is located between the source/drain regions 24 and the backside source/drain contact placeholder structures 20.

The exemplary first structure in the logic device region 100 and the exemplary second structure in the capacitor region 102 also include a middle-of-the-line (MOL) level that includes at least frontside source/drain contact structures 28 embedded in an upper portion of a multilayered frontside interlayer dielectric (ILD) structure 26. A lower portion of the multilayered frontside ILD structure 26 embeds the source/drain regions 24. Also present is a frontside BEOL structure 30 that is located on top of the MOL level. The frontside BEOL structure 30 is typically bonded to carrier wafer 32.

Each of the elements/components illustrated in FIG. 2 will now be described in more detail. As mentioned above, the substrate includes at least semiconductor device layer 14. In addition to the semiconductor device layer 14, the substrate can also include a semiconductor base layer 10 and/or an etch stop layer 12. Embodiments are contemplated in which the semiconductor base layer 10 and/or the etch stop layer 12 are omitted. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

The trench dielectric liner 16 is composed of a trench dielectric liner material such as, for example, silicon nitride. The trench dielectric material 18 is composed of any trench dielectric such as, for example, silicon dioxide. In some embodiments, the shallow trench isolation structure can have a topmost surface that is substantially coplanar with a topmost surface of the substrate (e.g., the semiconductor device layer 14). In other embodiments, the shallow trench isolation structure can have a topmost surface that is vertically offset (i.e., higher or lower) than a topmost surface of the substrate (e.g., the semiconductor device layer 14).

The backside source/drain contact placeholder structure 20 is composed of a fourth semiconductor material. The fourth semiconductor material is compositionally different from the second semiconductor material that provides the semiconductor device layer 14. Each backside source/drain contact placeholder structure 20 has a topmost surface that is substantially coplanar with a topmost surface of the semiconductor device layer 14.

When present, semiconductor buffer layer 22 is composed of a fifth semiconductor material. The fifth semiconductor material is typically compositionally different from the fourth semiconductor material that provides the backside source/drain contact placeholder structure 20; the fifth semiconductor material that provides the semiconductor buffer layer 22 can be compositionally the same as, or compositionally different from, the second semiconductor material that provides the semiconductor device layer 14. The presence of the semiconductor buffer layer 22 facilities epitaxial growth of the source/drain regions 24. The semiconductor buffer layer 22 is generally located above the topmost surface of the substrate (e.g., the topmost surface of the semiconductor device layer 14).

Each source/drain region 24 is composed of a sixth semiconductor material and a dopant. The sixth semiconductor material that provides the source/drain regions 24 can be compositionally the same as, or compositionally different from, the fifth semiconductor material. The dopant that is present in the source/drain regions 24 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region 24 can have a dopant concentration of from 4×10²⁰ atoms/cm³ to 3×10²¹ atoms/cm³.

The multilayered frontside ILD structure 26 includes two frontside ILD layers; the first frontside ILD layer represents the lower portion of the multilayered frontside ILD structure 26, while the second frontside ILD layer represent the upper portion of the multilayered frontside ILD structure 26. The first frontside ILD layer is composed of a first ILD material, while the second frontside ILD layer is composed of a second ILD material. The second ILD material can be compositionally the same as, or compositionally different from, the first ILD material. An ILD material is a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

Each frontside source/drain contact structure 28 is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. Each frontside source/drain contact structure 28 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The frontside BEOL structure 30 is composed of an interconnect dielectric region having frontside metal wiring embedded therein; the frontside metal wiring present in the frontside BEOL structure 30 is typically signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. It is noted that the frontside BEOL structure 30 is electrically connected (via a frontside source/drain contact structure 28) to one of the source/drain regions 24 of a transistor that is present in both the logic device region 100 and the capacitor region 102.

Carrier wafer 32 can include a semiconductor material as exemplified above. Carrier wafer 32 is bonded to the frontside BEOL structure 30 by a bonding dielectric layer (not shown). Illustrative examples of dielectric materials that are used as the bonding dielectric layer include, but are not limited to, tetraethyl orthosilicate (TEOS), SiO₂, silicon carbon nitride (SiCN) and/or carbon-doped silicon oxide (SiCOH).

The first exemplary structure and the second exemplary structure illustrated in FIG. 2 can be formed utilizing any conventional transistor fabrication process including, for example, a nanosheet transistor fabrication process. Following the conventional transistor fabrication process, a conventional MOL process is used in forming the second frontside ILD layer and the frontside source/drain contact structures 28. The first frontside ILD layer is typically formed during the transition fabrication process. The MOL process can include a metallization process in which frontside contact openings are formed by lithography and etching into the second frontside ILD layer, and thereafter each of the frontside contact openings is filled with at least a contact conductor material, as defined above. The filling of each frontside contact opening can include deposition of the contact conductor material followed by a planarization process such as, for example, chemical mechanical planarization (CMP). After MOL processing, a conventional frontside BEOL structure formation process is performed, and thereafter a bonding process can be used in bonding carrier wafer 32 to the frontside BEOL structure 30.

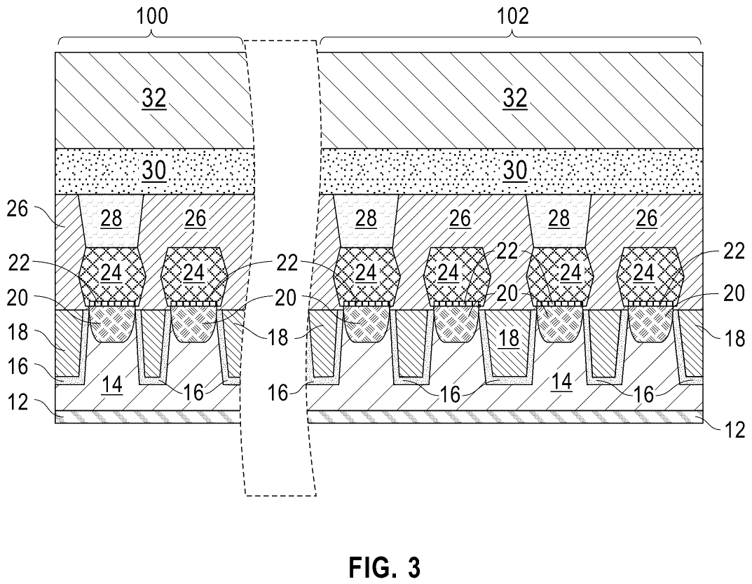

Referring now to FIG. 3, there is illustrated the first exemplary structure and the second exemplary structure shown in FIG. 2 after wafer flipping, and removal of semiconductor base layer 10. In the present application, backside processing begins by flipping the exemplary first structure and the exemplary second structure 180° to physically expose a backside of the structure. For clarity, the flipping step is not shown in the drawings. Flipping can be performed by hand or by utilizing a mechanical means such as, for example, a robot arm. After flipping, and in the illustrated embodiment, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12 of the substrate. The removal of the semiconductor base layer 10 can be omitted when no semiconductor base layer 10 is present in the substrate.

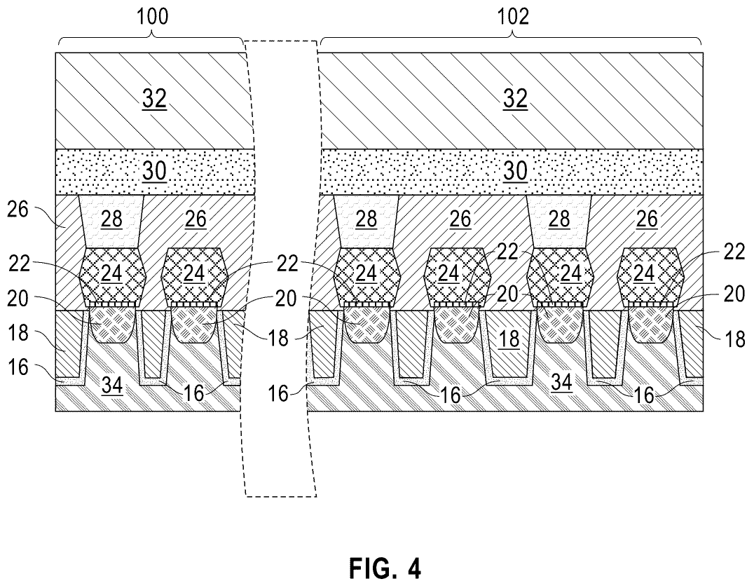

Referring now to FIG. 4, there is illustrated the first exemplary structure and the second exemplary structure shown in FIG. 3 after removing etch stop layer 12 and semiconductor device layer 14, and forming a backside ILD layer 34. The etch stop layer 12 can be removed utilizing a material removal process that is selective in removing the material that provides the etch stop layer 12. The removal of the etch stop layer 12 physically exposes the semiconductor device layer 14. It is noted that the removal of the etch stop layer 12 can be omitted when such a layer is not present. Following the removal of the etch stop layer 12, the semiconductor device layer 14 is removed utilizing a material removal process that is selective in removing the semiconductor device layer 14. The removal of the semiconductor device layer 14 physically exposes the trench dielectric liner 16 and each backside source/drain contact placeholder structure 20.

The backside ILD layer 34 is composed of an ILD material as mentioned above. The backside ILD layer 34 can be formed by deposition, followed by planarization. Deposition of the backside ILD layer 34 can include, for example, chemical vapor deposition (CVD), plasma enhanced chemical vapor deposition (PECVD) or spin-on coating. The backside ILD layer 34 contacts physically exposed surfaces of each backside source/drain placeholder structure 20 and the trench dielectric liner 16.

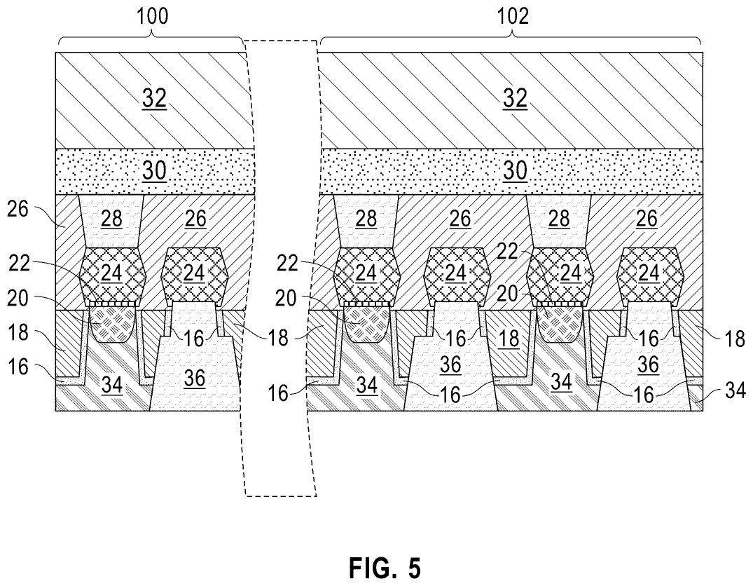

Referring now to FIG. 5, there is illustrated the first exemplary structure and the second exemplary structure shown in FIG. 4 after forming backside source/drain contact structures 36. The forming of the backside source/drain contact structures 36 includes a backside source/drain contact patterning process in which at least one patterned masking layer is formed on the backside ILD layer 34 that has openings that physically expose portions of the backside ILD layer 34 that coincide with areas in which backside source/drain contact structures 36 are to be formed. One or more etching processes are then used to physically expose some of the source/drain regions 24 of the first and second exemplary structures. The one or more etching processes remove the backside ILD layer 34 and the backside source/drain contact placeholder structure 20 that are not protected by the at least one patterned masking layer. The one or more etching processes can also remove the semiconductor buffer layer 22. In some embodiments, the semiconductor buffer layer 22 can remain. The one or more etching processes form a self-aligned backside source/drain contact opening in which the backside source/drain contact structures 36 are formed. Each backside source/drain contact structure 36 is composed of at least a contact conductor material as defined above for the frontside source/drain contact structures. Each backside source/drain contact structure 36 can also include one or more contact liners (not shown). In one or more embodiments, the contact liner (not shown) can include a diffusion barrier material as defined above. In one or more embodiments in which a contact liner is present, the contact liner (not shown) can include a silicide liner, such as Ti, Ni, NiPt, etc., and a diffusion barrier material, as defined above. Each backside source/drain contact structure 36 can be formed by a deposition process such as, for example, CVD, PECVD, atomic layer deposition (ALD) or sputtering, followed by a planarization process. As is shown, each backside source/drain contact structure 36 is in contact with one of the source/drain regions 24 that is present in each of the logic device region 100 and the capacitor region 102. Each backside source/drain contact structure 36 has an upper portion that has a first critical dimension and a lower portion that has a second critical dimension that is greater than the first critical dimension. Each backside source/drain contact structure 36 is self-aligned to one of the source/drain regions 24. Each backside source/drain contact structure 36 is in direct contact with a source/drain region 24 of a transistor.

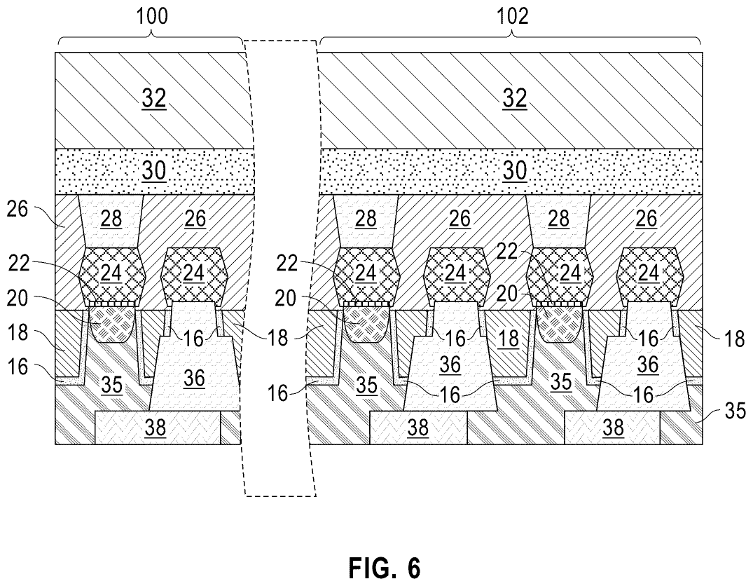

Referring now to FIG. 6, there is illustrated the first exemplary structure and the second exemplary structure shown in FIG. 5 after forming backside first level metal structures 38. Each backside first level metal structure 38 is formed by depositing an additional ILD layer to the backside ILD layer 34 to form multilayered backside ILD structure 35. The depositing of the additional ILD layer to the backside ILD layer 34 can include, for example, CVD, PECVD, or spin-on coating. The additional ILD layer is composed of an ILD material as mentioned above which can be compositionally the same as, or compositionally different from, the ILD material that provides the backside ILD layer 34. After depositing the additional ILD layer, the formation of the backside first level metal structure 38 continues by utilizing a metallization process. The metallization process includes forming an opening in the multilayered backside ILD structure 35 by lithography and etching. The opening physically exposes a portion of the backside source/drain contact structure 36. The opening is then filled with an electrically conductive metal or electrically conductive metal alloy. The filling includes deposition of the electrically conductive metal or electrically conductive metal alloy, followed by a planarization process. Exemplary electrically conductive metals include, but are not limited to, Cu, W, Al, Co, or Ru. An exemplary electrically conductive metal alloy is a Cu—Al alloy. As is illustrated, each backside first level metal structure 38 is electrically connected to a source/drain region of one of the transistors by a backside source/drain contact structure 36.

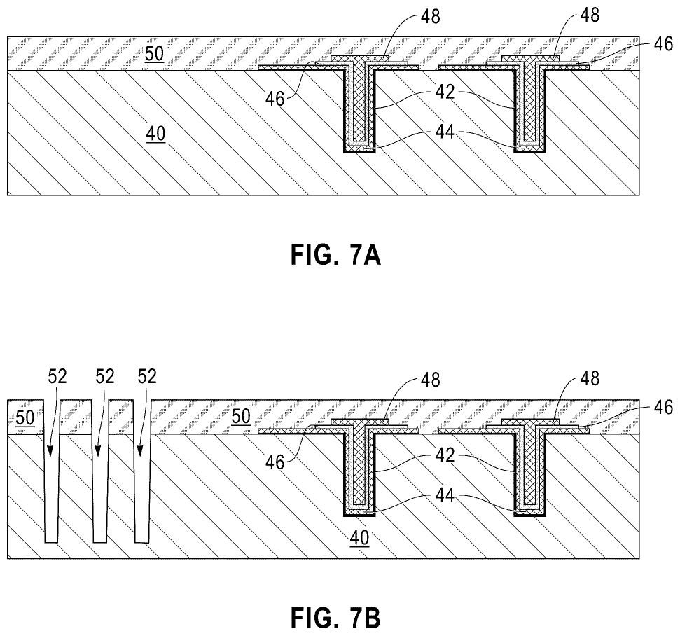

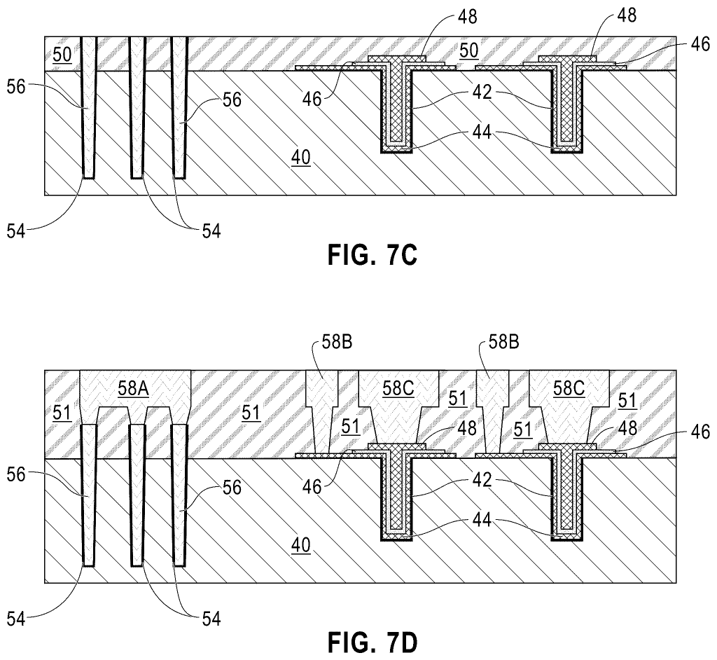

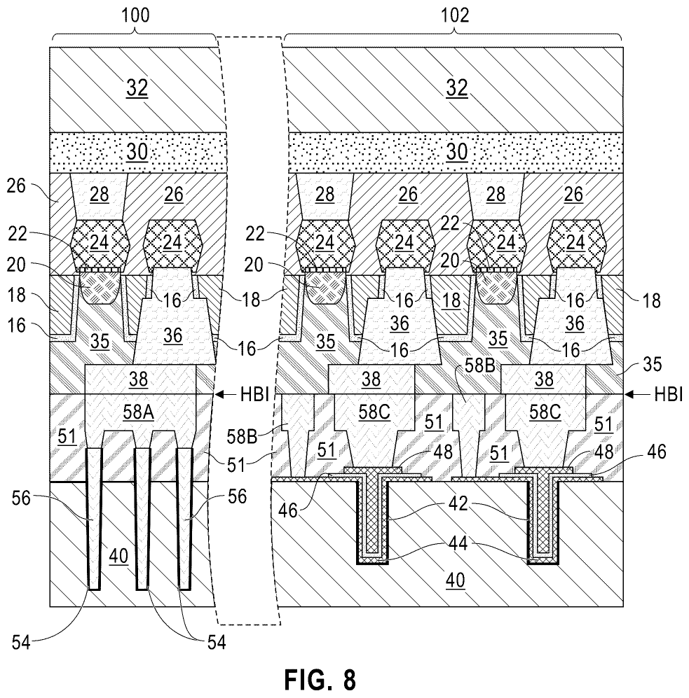

Instead of continuing the building of a deep trench capacitor in the capacitor region 102 by traditional backside processes, the present application deviates from traditional backside deep trench capacitor formation processes by forming a deep trench capacitor in a separate structure from the one depicted in FIG. 6 and thereafter a hybrid bonding process is used to form a hybrid bond between the separate structure containing the backside deep trench capacitor and the backside of the exemplary first and second structures shown in FIG. 6. The formation of the separate structure including the backside deep trench capacitor is shown in FIGS. 7A-7D, the hybrid bonding process is illustrated in FIG. 8.

Throughout the present application, the term “hybrid bond” denotes a dielectric-to-dielectric bond and a metal-to-metal bond such that a hybrid bonding interface is formed between the bonded dielectric materials and the bonded metals. Throughout the present application, the term “hybrid bonding interface” denotes an interface containing dielectric-to-dielectric bonding and metal-to-metal bonding. Notably, hybrid bonding refers to a 3D packing technique to connect semiconductor builds. Hybrid bonding forms connections of semiconductor structures through metal bond pads which are embedded in a dielectric layer at a bond interface on each semiconductor structure that is being bonded. The metal bond pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them. The dangling bonds and covalent bonding occurs in the present application.

Referring now to FIG. 7A, there is illustrated a third exemplary structure including a semiconductor substrate 40, a deep trench capacitor partially formed in a deep trench opening that is located in the semiconductor substrate 40, and a dielectric layer 50. The semiconductor substrate 40 includes one of the semiconductor materials mentioned above. The backside deep trench capacitor includes a first electrode plate 44, and a second electrode plate 48 that spaced apart by a capacitor dielectric 46. A deep trench capacitor dielectric liner 42 can optionally be present along a sidewall and a bottom surface of the first electrode plate 44. The first electrode plate 44 and the second electrode plate 48 can be single layered structures or muti-layered structures. The first electrode plate 44 and the second electrode plate 48 are composed of a conductive metal-containing material. In some embodiments, the first electrode plate 44 and the second electrode plate 48 are composed of a compositionally same conductive metal-containing material. In other embodiments, the first electrode plate 44 and the second electrode plate 48 are composed of a compositionally different conductive metal-containing materials. In the present application, the term “conductive metal-containing material” denotes a pure metal, a metal carbide compound or a metal nitride compound. Illustrative conductive metal-containing materials that can be used in providing the first electrode plate 44 and the second electrode plate 48 include, but are not limited to, titanium nitride and/or tantalum nitride. The capacitor dielectric 46 is composed of one of the high k gate dielectric materials mentioned above for the gate dielectric material of the gate structure. The deep trench capacitor dielectric liner 42 is composed of a diffusion barrier material as described above.

The backside deep trench capacitor can be formed by first forming a deep trench opening in the semiconductor substrate 40 by lithography and etching, The etch physically exposes a sub-surface of the semiconductor substrate 40; i.e., a surface between a topmost surface and a bottommost surface of the semiconductor substrate 40. The backside deep trench capacitor formation continues by depositing a layer of first conductive metal-containing material inside and outside of the backside deep trench opening, followed by depositing a layer of capacitor dielectric material on the layer of first conductive metal-containing material, followed by depositing a layer of the second conductive metal-containing material on the layer of capacitor dielectric material. In embodiments in which deep trench capacitor dielectric liner 42 is present, a layer of dielectric liner material is deposited inside and outside the backside deep trench opening prior to depositing the layer of first conductive metal-containing material. A lithographic patterning process can follow the deposition of the layer of dielectric material and/or the various layers that provide the backside deep trench capacitor. The lithographic patterning can be performed after each deposition step or during any combination of deposition steps.

Dielectric layer 50 is then formed on the semiconductor substrate 40 and on physically exposed portions of the backside deep trench capacitor that are present outside of the backside deep trench opening. Dielectric layer 50 is composed of an ILD material as mentioned above. The dielectric layer 50 can be formed by deposition of the ILD material, followed by a planarization process.

Referring now to FIG. 7B, there is illustrated the third exemplary structure shown in FIG. 7A after forming through via trenches 52 into the dielectric layer 50 and the semiconductor substrate 40. Each through via trench 52.extends entirely through the dielectric layer 50 and partially through the semiconductor substrate 40. The depth of each through via trench 52 is greater than a depth of the backside deep trench opening that now houses a lower portion of the backside deep trench capacitor. The through via trenches 52 can be formed by a lithographic patterning process.

Referring now to FIG. 7C, there is illustrated the third exemplary structure shown in FIG. 7B after forming a through via liner 54 and a through via metal structure 56 in each of the through via trenches 52. The through via liner 54 is composed of a diffusion barrier material as defined above. The though via liner 54 is optional and is not employed in some embodiments of the present application. Each through via structure 56 is composed of an electrically conductive metal or electrically conductive metal alloy, as also defined above. The through via liner 54 and the through via metal structure 56 are formed by depositing a layer of diffusion barrier material and a layer of an electrically conductive material, and thereafter performing a planarization process to remove the layer of diffusion barrier material and the layer of an electrically conductive material that is formed outside of the through via trenches 52. The layer of diffusion barrier material that remains inside each of the through via trenches 52 provides the through via liner 54, while the layer of an electrically conductive material that remains inside each of the through via trenches 52 provides the through via metal structure 56.

Referring now to FIG. 7D, there is illustrated the third exemplary structure shown in FIG. 7C after forming an additional dielectric layer, and forming interconnect structures in the additional dielectric layer. Collectively, the additional dielectric layer and dielectric layer 50 provides a multilayered dielectric structure 51. The additional dielectric layer is composed of an ILD material. The ILD material that provides the additional dielectric layer can be compositionally the same as, or compositionally different from, the ILD material that provides the dielectric layer 50. The additional dielectric layer can be formed by a deposition process such as, for example, CVD, PECVD or spin-on coating. In the present application, a lower portion of the backside deep trench capacitor is present in semiconductor substrate 40 and an upper portion of the backside deep trench capacitor is present in the multilayered dielectric structure 51.

The interconnect structures include a through-via interconnect structure 58A, a first electrode plate interconnect structure 58B and a second electrode plate interconnect structure 58C. The through-via interconnect structure 58A is in electrical contact with the through via metal structure 56, the first electrode plate interconnect structure 58B is in electrical contact with the first electrode plate 44 of the backside deep trench capacitor, and the second electrode plate interconnect structure 58C is in electrical contact with the second electrode plate 48. The interconnect structures are composed of an electrically conductive metal or electrically conductive metal alloy as defined above. The interconnect structures include a combined via/line interconnect structure which can be formed utilizing conventional techniques well known to those skilled in the art. For example, a dual damascene process can be used in forming each of the interconnect structures.

Referring now to FIG. 8, there is illustrated the first exemplary structure and the second exemplary structure shown in FIG. 6 after bonding the third exemplary structure illustrated in FIG. 7D on a backside of both the first and second exemplary structures. The bonding of the third exemplary structure on a backside of both the first and second exemplary structures illustrated in FIG. 6 includes a hybrid bonding process as defined above. The hybrid bonding process includes an alignment process in which some of the interconnect structures illustrated in FIG. 7D are aligned over the backside first level metal structures 38. Notably, the through-via interconnect structure 58A is aligned over the first level metal structure 38 present in the logic device region 100, and the second electrode plate interconnect structure 58C is aligned over the first level metal structure 38 present in the capacitor region 102. After alignment, the aligned structures are brought into intimate contact with each other, and thereafter the hybrid bonding process continues to provide the exemplary structure shown in FIG. 8. The bringing the aligned structures into intimate contact with each other can include the application of an external force which may or may not remain during a heating (i.e., annealing) step of the hybrid bonding process. The heating step of the hybrid bonding process provides a hybrid bonding interface, HBI, the includes metal-to-metal bonding and dielectric-to-dielectric bonding as described above. Notably, the metal-to-metal bonding occurs between the through-via interconnect structure 58A and the first level metal structure 38 that is present in the logic device region 100 and between the second electrode plate interconnect structure 58C and the first level metal structure 38 that is present in the capacitor region 102. Dielectric-to-dielectric bonding occurs between the multilayered dielectric structure 51 and the multilayered backside ILD structure 35. Heating can be performed from room temperature (i.e., 20° C.-25° C.) typically up to 450° C.; temperatures greater than 450° C. can also be used in the present application. The heating step of the hybrid bonding process is typically performed in an inert ambient such as, for example, He, Ar, Ne or mixtures thereof. After hybrid bonding, the temperature can be lowered back to room temperature. The hybrid bonding process can also include an activation process as described above.

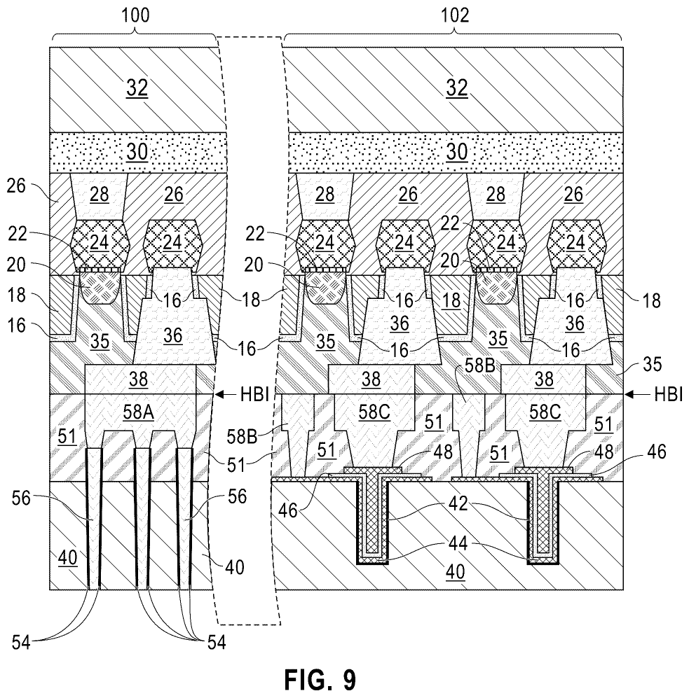

Referring now to FIG. 9, there is illustrated the bonded structure shown in FIG. 8 after thinning the semiconductor substrate 40 to reveal a bottommost surface of each through via metal structure 56. The thinning step can include a planarization process which removes a portion of the semiconductor substrate 40 and the through via liner 54 that is located on a bottommost surface of the through via metal structure 56.

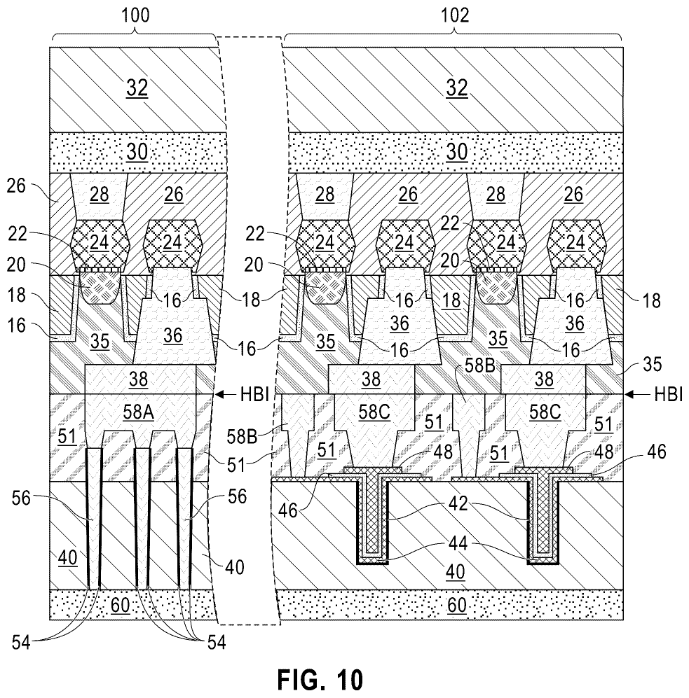

Referring now to FIG. 10, there is illustrated the exemplary structure shown in FIG. 9 after forming a backside BEOL structure 60. The backside BEOL structure 60 (which can deliver power from the backside of the device) is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. The backside BEOL structure 60 can be formed utilizing any well-known BEOL process including a damascene process or a subtractive metal etch process.

In the present application, the backside BEOL structure is electrically connected to one of the source/drain regions 24 in the logic device region 100 by a combination of through via metal structure 56, through-via interconnect structure 58A, first level metal structure 38 and backside source/drain contact structure 36. In the present application, the backside deep trench capacitor is electrically connected to one of the source/drain regions 24 in the logic device region 100 by a combination of second electrode plate interconnect structure 58C, first level metal structure 38 and backside source/drain contact structure 36.

Notably, FIG. 10 illustrates a semiconductor device in accordance with an embodiment of the present application. Notably, FIG. 10 illustrates a semiconductor device that includes a first transistor located in a capacitor region 102, a backside deep trench capacitor (including first electrode plate 44, and second electrode plate 48 spaced apart by capacitor dielectric 46) located beneath the first transistor, and a backside BEOL structure 60 located beneath the backside deep trench capacitor. In this embodiment, the backside deep trench capacitor is electrically connected to source/drain region 24 of the first transistor by a combination of a second plate electrode interconnect structure 58C, first level metal structure 38 and backside source/drain contact structure 36 and a hybrid bonding interface, HBI, is present between the second plate electrode interconnect structure 58C and the first level metal structure 38.

In some embodiments, the semiconductor device further includes a second transistor located in a logic device region 100 that is located adjacent to the capacitor region 102, in which the backside BEOL structure 60 is electrically connected to a source/drain region 24 of the second transistor by a combination through via structure 56, through-via interconnect structure 58A, first level metal structure 38 that is present in the logic device region 100 (herein referred to as a logic device first level metal structure) and backside source/drain contact structure 36 that is present in the logic device region 100 (herein referred to as a logic device backside source/drain contact structure). A hybrid bonding interface is present between the through-via interconnect structure 58A and the logic device first level metal structure. In such embodiments, the backside source/drain contact structure 36 in the capacitor region 102 and is in direct contact with the source/drain region 24 of the first transistor, and the logic device backside source/drain contact structure is in direct contact with the source/drain region 24 of the second transistor.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first transistor located in a capacitor region;
a backside deep trench capacitor located beneath the first transistor; and
a backside back-end-of-the-line (BEOL) structure located beneath the backside deep trench capacitor, wherein the backside deep trench capacitor is electrically connected to a source/drain region of the first transistor by a combination of a second plate electrode interconnect structure, a first level metal structure, and a backside source/drain contact structure, and wherein a hybrid bonding interface is present between the second plate electrode interconnect structure and the first level metal structure.

2. The semiconductor device of claim 1, wherein the backside deep trench capacitor comprises a first electrode plate and a second electrode plate that are spaced apart by a capacitor dielectric, wherein the second electrode plate is in electrical contact with the second plate electrode interconnect structure.

3. The semiconductor device of claim 2, further comprising a first electrode plate interconnect structure in electrical contact with the first electrode plate of the deep trench capacitor.

4. The semiconductor device of claim 1, wherein the backside deep trench capacitor has a lower portion present in a semiconductor substrate, and an upper portion present in a multilayered dielectric structure.

5. The semiconductor device of claim 1, further comprising a frontside BEOL structure located above the first transistor.

6. The semiconductor device of claim 1, wherein the backside source/drain contact structure has an upper portion having a first critical dimension and a lower portion having a second critical dimension, wherein the second critical dimension is greater than the first critical dimension.

7. The semiconductor device of claim 1, wherein the backside source/drain contact structure is in direct contact with the source/drain region of the first transistor.

8. The semiconductor device of claim 1, further comprising a semiconductor buffer layer located between the backside source/drain contact structure and the source/drain region of the first transistor.

9. The semiconductor device of claim 1, further comprising a second transistor located in a logic device region that is located adjacent to the capacitor region, wherein the backside BEOL structure is electrically connected to a source/drain region of the second transistor by combination of a through via structure, a through-via interconnect structure, a logic device first level metal structure and a logic device backside source/drain contact structure.

10. The semiconductor device of claim 9, wherein the hybrid bonding interface is present between the through-via interconnect structure and the logic device first level metal structure.

11. A semiconductor device comprising:
a first transistor and a backside deep trench capacitor located in a capacitor region;
a second transistor located in a logic device region that is located adjacent to the capacitor region; and
a backside back-end-of-the-line (BEOL) structure located beneath the backside deep trench capacitor and beneath the second transistor, wherein the backside deep trench capacitor is electrically connected to a source/drain region of the first transistor by a combination of a second plate electrode interconnect structure, a first level metal structure and a backside source/drain contact structure, and the backside BEOL structure is electrically connected to a source/drain region of the second transistor by a combination of a through via structure, a through-via interconnect structure, a logic device first level metal structure and a logic device backside source/drain contact structure, and wherein a hybrid bonding interface is present between the second plate electrode interconnect structure and the first level metal structure and between the through-via interconnect structure and the logic device first level metal structure.

12. The semiconductor device of claim 11, wherein the backside deep trench capacitor comprises a first electrode plate and a second electrode plate that are spaced apart by a capacitor dielectric, wherein the second electrode plate is in electrical contact with the second plate electrode interconnect structure.

13. The semiconductor device of claim 12, further comprising a first electrode plate interconnect structure in electrical contact with the first electrode plate of the deep trench capacitor.

14. The semiconductor device of claim 11, wherein the backside deep trench capacitor has a lower portion present in a semiconductor substrate, and an upper portion present in a multilayered dielectric structure.

15. The semiconductor device of claim 11, further comprising a frontside BEOL structure located above the first transistor and the second transistor.

16. The semiconductor device of claim 11, wherein both of the backside source/drain contact structure and the logic device backside source/drain contact structure has an upper portion having a first critical dimension and a lower portion having a second critical dimension, wherein the second critical dimension is greater than the first critical dimension.

17. The semiconductor device of claim 11, wherein the backside source/drain contact structure and is in direct contact with the source/drain region of the first transistor, and the logic device backside source/drain contact structure is in direct contact with the source/drain region of the second transistor.

18. The semiconductor device of claim 11, further comprising a semiconductor buffer layer located beneath the source/drain region of the first transistor and the source/drain region of the second transistor.
